(19) United States
(12) Patent Application Publication
(10) Pub. No.: US 2026/0015226 A1
(43) Pub. Date: Jan. 15, 2026

(54) METHOD FOR PRODUCING A MEMS MIRROR ARRAY, AND MEMS MIRROR ARRAY

(71) Applicant: Carl Zeiss SMT GmbH, Oberkochen (DE)

(72) Inventors: Yanko SAROV, Aalen (DE); Katharina BROCH, Aalen (DE); Hartmut ENKISCH, Aalen (DE); Sebastian STROBEL, Aalen (DE); Joern WEBER, Aalen (DE); Fabian HAACKER, Aalen (DE); Johannes EISENMENGER, Aalen (DE); Markus HAUF, Aalen (DE)

(21) Appl. No.: 19/337,492

(22) Filed: Sep. 23, 2025

Related U.S. Application Data
(63) Continuation of application No. PCT/EP2024/059174, filed on Apr. 4, 2024.

(30) Foreign Application Priority Data
Oct. 6, 2023 (DE) 10 2023 203 205.8

(51) Int. Cl. B81C 1/00; G02B 26/08; G03F 7/00

(52) U.S. Cl. CPC B81C 1/00714; G02B 26/0833; G03F 7/702; G03F 7/70291; B81C 2201/014; B81C 2201/0176; B81C 2201/053; B81C 2201/056; B81C 2203/0118

(57) ABSTRACT

A method for producing a MEMS mirror array such as can be used, e.g. in photolithography, and a corresponding MEMS mirror array, can reduce issues possibly resulting from environmental influences.

### CROSS-REFERENCE TO RELATED APPLICATIONS

The present application is a continuation of, and claims benefit under 35 USC 120 to, international application No. PCT/EP2024/059174, filed Apr. 4, 2024, which claims benefit under 35 USC 119 of German Application No. 10 2023 203 205.8, filed Apr. 6, 2023. The entire disclosure of each of these applications is incorporated by reference herein.

### FIELD

The disclosure relates to a method for producing a MEMS mirror array such as can be used e.g. in photolithography, and to a corresponding MEMS mirror array.

### BACKGROUND

Photolithography is employed for producing microstructured components, such as e.g. integrated circuits. The projection exposure apparatus used here comprises an illumination system and a projection system. The image of a mask (also referred to as reticle) illuminated by the illumination system is projected in reducing fashion via the projection system onto a substrate, for example a silicon wafer, which is coated with a light-sensitive layer and arranged in the image plane of the projection system, in order to transfer the mask structure to the light-sensitive coating of the substrate.

In illumination systems, for example projection exposure apparatuses designed for the EUV range, i.e. at exposure wavelengths of 5 nm to 30 nm, in general two facet mirrors are arranged in the beam path between the actual exposure radiation source and the mask to be illuminated, which mirrors help allow the radiation to be homogenized basically in a manner comparable with the general of a fly's eye condenser. The facet mirror closer to the exposure radiation source in the beam path is often a so-called field facet mirror, and the other mirror a so-called pupil facet mirror.

In order to be able to produce different intensity and/or angle-of-incidence distributions during the illumination of the mask, it is known for the facets of at least one of the two facet mirrors—for example those of the field facet mirror—to be formed from one or more electromechanically individually pivotable micromirrors. This is correspondingly disclosed e.g. in WO 2012/130768 A2.

In order to be able to attain a small size of the individual micromirrors, it is known to embody groups of micromirrors in the form of a so-called MEMS mirror array, namely a mirror array composed of microelectromechanical systems (MEMS).

In the case of a MEMS mirror array, a multiplicity of small mirror elements are each mounted individually movably relative to a common base. For each mirror element, provision is made of at least one actuator which enables the mirror element to be adjusted along a respectively predefined degree of freedom. The mirror elements are often pivotable about two axes running perpendicular to one another and parallel to the base, actuators then also being provided in a sufficient number to enable the mirror element to be pivoted mutually independently about precisely these axes. For the individual mirror elements, provision can also be made of sensors which make it possible to determine the position of the mirror element relative to the base in order thus to be able to monitor the alignment of the mirrors. One embodiment for the mirrors of a MEMS mirror array is described in DE 10 2015 204 874 A1.

A method for producing a micromirror or a MEMS mirror array comprising a plurality of such micromirrors is disclosed—together with further details concerning a possible configuration of the micromirror—in DE 10 2015 220 018 A1.

As explained therein, inter alia, MEMS systems and for example MEMS mirror arrays are produced in a manner comparable with semiconductors and, for example, by comparable methods. Consequently, a considerable proportion of, for example, the mechanical structure of the mirrors of a MEMS mirror array is regularly composed of silicon (Si), for example monocrystalline or polycrystalline silicon, for which there are established processing methods borrowed from semiconductor production, and so the actual production of MEMS mirror arrays is possible in general for a person skilled in the art.

In the case of the purpose of use for photolithography, a MEMS mirror array is used in the region of the illumination system in which in general a vacuum prevails at least during production operation. However, small amounts of hydrogen as so-called purge gas are often introduced into this vacuum in order to remove contamination from specific regions of the illumination system and/or from mirror surfaces. This hydrogen may interact with the exposure radiation within the illumination system and ionize to form a hydrogen plasma. This can apply to an EUV exposure radiation having a wavelength of 13.5 nm.

The hydrogen, for example if ionized, may react with the silicon of the MEMS mirror array, and for example the structure thereof, and result in outgassing e.g. of silicon hydroxide; this process is also referred to as hydrogen-induced outgassing (HIO). The outgassing can give rise to so-called hydrogen embrittlement and weakening of the material strength of filigree silicon structures. Furthermore, there is the risk of the outgassed substances depositing on the optical surfaces within the illumination system or—if arranged within the same vacuum chamber—the projection system and thus degrading them.

Moreover, it is possible for the MEMS mirror arrays to be attacked by environmental influences other than hydrogen or hydrogen plasma, which either adversely affect the structural integrity and/or the functioning of the MEMS mirror array or cause substances to be released which may deposit on the optical surfaces.

### SUMMARY

The present disclosure seeks to reduce issues possibly resulting from environmental influences on MEMS mirror arrays within projection exposure apparatuses. This can include avoiding or at least reducing hydrogen-induced outgassing of substances in the case of MEMS mirror arrays within projection exposure apparatuses.

In an aspect, the disclosure provides a method for producing a MEMS mirror array for photolithography having a predefined number of individual mirrors adjustable by at least one degree of freedom, comprising the following steps:
a) providing a mirror wafer comprising a number of mirror sections separated from one another by release sections, the number corresponding to the number of adjustable mirrors;
b) providing an actuator wafer comprising a number of actuator sections corresponding to the number of adjustable mirrors, wherein the actuator sections are spaced apart from one another according to the mirror sections of the mirror wafer and the individual actuator sections are provided with at least one functional structure;
c) joining together the mirror wafer and the actuator wafer in such a way that a mirror section and an actuator section are in each case fixedly connected to one another in defined regions; and
d) removing at least the release sections of the mirror wafer, such that the individual mirror sections can be adjusted relative to the respective actuator sections in each case by at least one degree of freedom using at least one portion of the functional structures;
wherein before or after at least one of the aforementioned steps, at least regions of the mirror wafer and/or of the actuator wafer are provided with a protective layer against environmental influences for protecting the underlying material against hydrogen-induced outgassing.

The disclosure relates to a MEMS mirror array for photolithography having a predefined number of individual mirrors adjustable by at least one degree of freedom, which MEMS mirror array was produced in a method according to the disclosure.

Some terms used in connection with the present disclosure will be explained:

In the case of a “MEMS mirror array” for photolithography, provision is made of a predefined number of individual mirrors which are arranged closely alongside one another in a two-dimensional grid and can be adjusted individually in at least one degree of freedom. In this case, at least 4, at least 16, at least 64, at least 250 or at least 1000 mirrors can be provided, the mirrors can be arranged in a square or hexagonal grid. As an exception, a mirror array can also comprise just one mirror.

The outer contour of the active reflective surface of each of the individual mirrors can be configured as round or polygonal, i.e. can be for example triangular, quadrilateral or hexagonal. The edge length in the case of a polygonal configuration here can be in the range of 10 μm to 10 mm, such as in the range of 100 μm to 4 mm, for example in the range of 0.6 mm to 1.5 mm, it being optional for all the edges to have the same length. All the mirrors of the MEMS mirror array can have identically embodied reflection surfaces; this is not mandatory, however.

The “reflection surface” of a mirror is that surface which in general is reflective to light of at least one predefined wavelength, namely for example the wavelength(s) of the exposure for photolithography, and which, during the use of the MEMS mirror array at least in an envisaged state of a mirror, actually serves for deflecting light for further use. For example, inner regions of a MEMS mirror array which, owing to production, possibly in general have the desired reflective properties, but are not actively used at any time for the deflection of light, e.g. for exposure purposes, therefore do not constitute “reflection surfaces” within the meaning of this disclosure. The actual reflection surfaces of the mirrors can be embodied in plane fashion. However, it is also possible for the surface to be embodied in concavely or convexly curved fashion. Moreover, any other shaping of the reflection surfaces of a mirror is possible.

In general, a high integration density of the mirrors in a MEMS mirror array is striven for. The integration density can be expressed here e.g. by way of the proportion of the reflection surface of the mirrors that is formed by the individual mirrors in relation to the total surface area of the MEMS mirror array (the so-called “fill factor”). The fill factor can be at least 0.5, such as at least 0.75, for example at least 0.9.

A mirror is “adjustable by at least one degree of freedom” if it can be adjusted independently of other possible degrees of freedom. For example, rotational degrees of freedom are relevant here to MEMS mirror arrays. Optionally, a mirror can be pivoted about an axis perpendicular to the normal to the reflection surface of the mirror. It is particularly possible for a mirror to be pivoted independently about two axes arranged perpendicular to one another, the two axes mentioned optionally running perpendicular to the normal to the reflection surface in the case of a predefined zero alignment of the mirror. Particularly if the mirrors have a hexagonal shape and/or are arranged in a hexagonal grid, it may be desired for a mirror to be pivoted about three axes arranged in a common plane with an angular separation of 60° in each case. The zero alignment of all the mirrors of a mirror array can be chosen such that all the normals to the reflection surfaces of the individual mirrors run parallel to one another and/or parallel to the normal to the overall surface of the MEMS mirror array.

“Functional structures” in the region of mirror sections of the mirror wafer or actuator sections of the actuator wafer are such structures which are of importance during the joining of mirror wafer and actuator wafer or else for the later function of the MEMS mirror array. In this regard, the functional structures can be those regions at which mirror wafer and actuator wafer are actually connected to one another. For this purpose, the regions in question can optionally also have a particular shaping which enables or improves the connection, or else enables the later movability of the mirror. However, functional structures can also be such structures which, after completion of the MEMS mirror array, alone or together with other functional structures, form e.g. an actuator or a sensor which enables a movement by a predefined degree of freedom to be effected or monitored. They can also include structures which enable the electrical linking of actuators and/or sensors.

The disclosure involves the concept that negative environmental influences can be reduced, if not even completely prevented, by the provision of a suitable protective layer. For example, suitable selection of the protective layer can make it possible to reduce or completely prevent hydrogen-induced outgassing in the case of a MEMS mirror array. In this case, the disclosure can involve the integration of applying the protective layer against environmental influences into the process for producing a MEMS mirror array, for example for photolithography applications, resulting in relatively high imperviousness and uniformity of the protective layer against environmental influences. In order to offer comprehensive protection, the protective layer can be applied in planar fashion to, such as all, surfaces which in general are at risk vis-à-vis environmental influences, such as hydrogen-induced outgassing.

In a method according to the disclosure for producing a MEMS mirror array for photolithography, provision can be made for providing both a mirror wafer and an actuator wafer, which in the course of the method are joined together and subsequently processed further in order ultimately to create a functional MEMS mirror array.

The mirror wafer is typically a planar structure which generally is composed at least partly, if not even for the most part, of monocrystalline silicon. This mirror wafer is subdivided into mirror sections which, after the end of the production method, will in each case form the movable mirror with the reflection surface. Consequently, the number of mirror sections can correspond to the number of mirrors of the MEMS mirror array to be produced. At the time when the mirror wafer is provided, the individual mirror sections can be ascertainable on the wafer on the basis of elevations or depressions at least on one side of the mirror wafer, although that is not mandatory.

At the time when the mirror wafer is provided, optionally at least some functional structures may in each case already have been provided in the region of each mirror section on the wafer; this is not a necessity, however. The functional structures can be recognizable on the basis of elevations or depressions at the time when the mirror wafer is provided. However, it is also possible for the functional structures to be integrated into a mirror wafer with plane surfaces. The functional structures can then be uncovered in a subsequent processing step; this is not absolutely necessary, however.

The provision of functional structures already at the time when the mirror wafer is provided can mean that corresponding functional structures can be provided without any issues even in regions of the mirror sections which are possibly no longer accessible, or accessible only with difficulty, after the envisaged later joining together of the mirror wafer with the actuator wafer. This analogously also applies, of course, to functional structures to be provided on the actuator wafer.

At the time when the mirror wafer is provided, the individual mirror sections on the mirror wafer can all be connected to one another by release sections. Using the release sections—which are to be removed in a later method step—the mirror sections ca be fixedly connected to one another, such that a relative movement of the mirror sections with respect to one another is not possible, nor is an individual treatment of the individual mirror sections involved. Mirror wafer processing steps prior to providing the mirror wafer, and also the handling of the mirror wafer in the course of the method according to the disclosure can thus be greatly simplified.

Besides the mirror wafer, an actuator wafer is provided, too, which generally is composed at least partly, if not even for the most part, of polycrystalline silicon. Alternatively, the actuator wafer may of course also be composed of monocrystalline silicon. Analogously to the mirror sections on the mirror wafer, actuator sections can be provided on the actuator wafer, and they each likewise can comprise at least one functional structure. In this case, the actuator sections can likewise be spaced apart from one another, wherein the material of the actuator wafer in the regions between the actuator sections, even though dimensioned identically, is not removed at a later time, in contrast to the release sections of the mirror wafer.

The provided wafers—namely mirror wafer and actuator wafer—can be joined together in a subsequent step. In this case, the two wafers can be placed one above the other such that respective mirror sections of the mirror wafer correspond to respective actuator sections of the actuator wafer, and the respective sections can be fixedly connected to one another in regions defined therefor.

The two wafers can be aligned with one another for the joining here with a positional accuracy in the plane of the common contact area of better than 5 μm, such as better than 2 μm, for example better than 1 μm. The mirror sections of the mirror wafer can thus be highly precisely aligned vis-à-vis their respective actuator sections and then connected to the actuator sections.

In a further step, at least the release sections of the mirror wafer are then completely removed. For example, the release sections can be removed by etching, wherein with the aid of suitable etch stop coatings or originally inner etch stop layers (referred to overarchingly hereinafter as etch stop layers), it is desirable to ensure that exclusively structural regions that are not desired (anymore) are removed. Corresponding etch stop layers and their application or integration in semiconductor or semiconductor-like structures are known in general. Particularly if portions of the structure to be removed or to be retained are composed of silicon, such as polycrystalline silicon, e.g. silicon dioxide can be used as etch stop layer—provided, of course, that the etching medium used does not remove silicon dioxide. Even if the silicon dioxide, which is less susceptible to environmental influences, such as hydrogen-induced outgassing, in comparison with (polycrystalline) silicon, permanently remains in the created structure and possibly forms relatively small portions of the structure surface there, the silicon dioxide can be applied for the selective etching as an etch stop in general only selectively or in structured fashion. Consequently, extensive portions of the surface of the structure produced by the etching process can still be formed by (polycrystalline) silicon that is to be protected against environmental influences, such as hydrogen-induced outgassing.

The outer surface of the mirror sections that is intended to form the reflection surface at the end of the method can also be protected against damage during the production method, such as a result of the etching, via the application and suitable curing of a photoresist layer. Corresponding and suitable “photoresist layers” are sufficiently known from semiconductor production. The photoresist layer can be removed again at a suitable time. As an alternative to a photoresist layer, e.g. layers composed of silicon dioxide, silicon nitride, aluminium oxide or aluminium can also be provided. A combination of the layers mentioned in a multilayer construction is also conceivable.

If the release sections are removed by an etching method, possibly concealed and recessed functional structures can also be uncovered in the course of this. Moreover, it is thus possible, for example, to remove any partial structure possibly undesirably obstructing the at least one degree of freedom of each individual mirror.

The removal of at least the release sections makes it possible, in general, that the mirror sections that are then separated from one another can be adjusted by at least one degree of freedom relative to the respective actuator section to which they are then solely connected. At least one portion of the functional structures already present at the provided actuator wafer, and optionally also at the mirror wafer, can be used for precisely this adjustment. As already explained, the functional structures can be a particular structural configuration, e.g. flexures for enabling one or more degrees of freedom. Alternatively, it is possible, for example, for functional structures on the mirror section and on the actuator section to cooperate in order thus to form an actuator or a sensor which enables a movement by a predefined degree of freedom to be effected or monitored.

Method steps described above are only certain steps for producing a MEMS mirror array which are desirable for the method according to the disclosure. Any further (intermediate) steps can be provided before, between and after the method steps mentioned. By way of example, additional surface processing steps, such as cleaning or chemical mechanical polishing, can be provided in order to increase the surface quality for a subsequent step. Moreover, it is possible to carry out steps in parallel with the steps mentioned or to integrate such steps into a common method step. One example thereof is the optional removal of undesired structures in the course of removing the release sections.

According to the disclosure, however, it is provided that before or after at least one of the above thoroughly explained steps for producing a MEMS mirror array for photolithography, at least regions of the mirror wafer and/or of the actuator wafer can be provided with a protective layer for protecting the underlying material against environmental influences. For example, the protective layer can protect against hydrogen-induced outgassing, for which purpose it is desirable for the material of the protective layer to be chosen suitably.

In this case, the protective layer against environmental influences can be provided at least on all surfaces of the completed MEMS mirror array which are susceptible to expected environmental influences and/or hydrogen-induced outgassing, i.e. which—in the case of expected environmental influences—are subject to the risk of the functioning of the MEMS mirror array being impaired or the release of substances, such as hydrogen-induced outgassing. By virtue of all surfaces in question being provided with a corresponding protective layer against environmental influences, this can greatly reduce the risk of negative consequences of environmental influences on the functionality of the MEMS mirror array and/or the unwanted release of substances during operation. Besides the structural elements of the MEMS mirror array, functional elements, too, such as e.g. electrode combs of actuators and/or sensors, can be protected with the protective layer against environmental influences.

Depending on the ultimately chosen details of the method for producing a MEMS mirror array for photolithography—within the scope according to the disclosure—the protective layer against environmental influences can be applied at different times.

For example, at least one portion of the protective layer against environmental influences can be applied after the removal of at least the release sections of the mirror wafer. At this time the surfaces which in general are susceptible to expected environmental influences and/or hydrogen-induced outgassing lie exposed for the most part, if not even completely, and so the desired protective effect can be comprehensively achieved by depositing the protective layer against environmental influences on all surfaces that lie exposed.

Alternatively or additionally, it is possible to provide at least portions of the ultimately desired protective layer against environmental influences in regions suitable therefor already on the mirror wafer and/or the actuator wafer. For example, it is also possible to integrate the protective layer into the mirror wafer and/or actuator wafer in such a way that the protective layer is only uncovered in the subsequent processing steps, such as by material arranged thereon being removed.

If the removal of material and/or the release sections takes place in an etching process, it is optional—including when divorced from possible application or integration prior to provision of mirror wafer and/or the actuator wafer—for the protective layer for at least some possible etching processes to be an etch stop, for example for the removal of at least the release sections by etching. If the protective layer can serve as an etch stop, this can help ensure that the protective layer is in general not damaged by etching processes provided after its application or integration. At the same time, systematically starting from a certain point in time unwanted material, such as e.g. the release sections, in regions at least partly delimited by the protective layer, can be removed in a targeted manner just like possible material residues and other contaminants before previous method steps. If the protective layer itself cannot serve as an etch stop, it is also possible to provide, instead of the protective layer on its own, a multilayer construction comprising protective layer with—arranged thereabove—etch stop layer, e.g. composed of silicon dioxide.

It is furthermore desirable for, before or after at least one of the aforementioned steps and before or after applying the protective layer, a reflection coating to be applied at least in regions of the individual mirror sections that are provided as reflection surface, the reflection coating being reflective to light of at least one predefined wavelength. In general, it is only a corresponding coating that makes a mirror section sufficiently reflective. In this case, the reflection coating is to be configured in a manner suitably adapted to the wavelength provided for photolithography and can e.g. also have a multilayer construction. If a MEMS mirror array is provided for an EUV projection exposure apparatus, for example, and are therefore able to reflect well light having a wavelength of 13.5 nm, such as a multilayer construction composed of molybdenum and silicon layers can be provided as reflection coating, the individual layers each having a thickness of only a few nanometres. Such a coating is known to reflect the EUV exposure radiation sufficiently well. Monolayer reflection coatings composed of other material may be sufficient for other wavelengths or wavelength ranges.

If the reflection coating is applied before the removal of at least the release sections of the mirror wafer, the individual mirror sections are still fixedly and immovably integrated in the mirror wafer. This simplifies a highly precise, for example homogeneous and reproducible, application of the reflection coating, for example if the latter is embodied in multilayer fashion. However, it is then regularly desirable to provide a layer that is also to be removed again later, such as e.g. a photoresist layer or an inorganic layer, on the reflection coating in order to suitably protect the latter during the subsequent method steps, such as the removal of the release sections. In this procedure it is unimportant, in general, whether the reflection coating is applied before or after the joining together of mirror wafer and actuator wafer.

Alternatively, it is possible to apply the reflection coating only after the release sections have been removed. Since in this stage the mirror regions can generally already be moved relative to the respective actuator region in at least one degree of freedom, increased challenges can arise with respect to implementing a highly precise coating. However, exclusively temporarily providing an additional layer for protecting the reflection coating is generally dispensable.

If the reflection coating is applied after the protective layer against environmental influences has been applied, there is the possibility of this protective layer also being arranged in the regions provided for the reflection coating. If the protective layer against environmental influences is suitable as a foundation for the reflection coating in regard to surface quality, hardness and adhesion, the reflection coating can be applied directly on this protective layer. Depending on the reflection coating, it can be desirable here for this reflection coating to be electrically linked. If the protective layer against environmental influences is not electrically conductive, for this purpose provision can be made of suitable vias through the protective layer, which are created and optionally filled with conductive material at the latest before the application of the reflection coating. Vias can be created using plasma etching, ion milling, ion or electron polishing, laser ablation or selective atomic layer deposition etching. As electrically conductive filling material for the vias, it is possible to use silicon or alternatively the material for the reflection coating, provided that this material is electrically conductive. Alternatively, it is conceivable for a protective layer that is insulating, in general, to be made sufficiently conductive by suitable subsequent processing. For this purpose, e.g. the introduction of ions by irradiation, directional deposition or incandescence can be used to reduce the resistivity of the protective layer for example to a range of 1 to 1000 MΩ×m²/m.

Alternatively, it is possible firstly to remove the protective layer against environmental influences from the regions in question and only then to apply the reflection coating.

If the reflection coating is applied before the protective layer against environmental influences is applied, this protective layer, after being applied, will regularly extend over the reflection coating. If the protective layer is sufficiently transmissive to light of that/those wavelength(s) which the reflection coating is intended to reflect, the protective layer can remain on the reflection coating. In this case, it is desirable, of course, to ensure that the surface quality of the reflection coating and of the protective layer, for example with regard to roughness, is good enough not to generate any unwanted optical effects. Alternatively, it is possible to at least partly remove the protective layer from the reflection coating. In order to facilitate this, a temporary layer can also be provided between reflection coating and protective layer against environmental influences, and protects the reflection coating for example also during detachment of the protective layer.

In the course of the production method according to the disclosure, it is possible, of course, for a person skilled in the art to provide intermediate layers between the explicitly mentioned layers and coatings. These can be, for example, temporarily provided intermediate layers which e.g. serve to protect an underlying layer or coating and/or facilitate the removal of a layer or coating lying thereon. If an intermediate layer is intended to remain permanently in a MEMS mirror array produced according to the disclosure, it is desirable to ensure that the intermediate layer does not adversely impair the functioning—evident from the above—of the MEMS mirror array and the individual layer.

For a person skilled in the art, it is furthermore self-evident, as desired, to examine surfaces for the desired surface quality before the application of a layer or coating and if appropriate to perform processing steps in order to attain the desired surface quality.

It is also possible, of course, in arbitrary intermediate steps, to remove layers or coatings in regions in which they are no longer desired.

Appropriate material for the protective layer against environmental influences is, for example, electrically insulating substances such as aluminium oxide (AlₓO_{y}) or titanium oxide (TiₓO_{y}). However, electrically conductive substances or a multilayer construction are/is also possible. For example, the protective layer against environmental influences can be composed of a substance which is used for the reflection coating in the reflection surface or at least one layer thereof.

In an embodiment variant that possibly involves separate protection, it is also possible to dispense with joining together a provided mirror wafer and a provided actuator wafer, rather the corresponding method steps (a) to (c) are replaced with a single step of providing a combined wafer. The combined wafer here substantially constitutes the combination of mirror wafer and actuator wafer as otherwise attained by the joining together in accordance with step (c), in each case in any of the configurations outlined above. In the case of the combined wafer, the interspaces that possibly remain when joining together mirror wafer and actuator wafer are generally just filled with material, which however can be removed again as desired in a later processing step. A corresponding combined wafer can be produced, in general, by known methods of material application and/or removal of material, which take place in each case selectively and/or only regionally. Step (d) and providing at least regions of a combined wafer with a protective layer for protecting the underlying material against environmental influences, for an arbitrarily produced combined wafer, can in any case be carried out analogously to the method described on the basis of mirror wafer and actuator wafer being joined together.

For elucidation of the MEMS mirror array according to the disclosure, reference is made to the explanations above.

### BRIEF DESCRIPTION OF THE DRAWINGS

The disclosure will now be described by way of example on the basis of certain embodiments with reference to the accompanying drawings, in which:

FIG. 1: shows a schematic illustration of a projection exposure apparatus for photolithography comprising MEMS mirror arrays produced according to the disclosure;

FIGS. 2A-2E: show a schematic illustration of a first exemplary embodiment of a method according to the disclosure for producing a MEMS mirror array which can be used in the projection exposure apparatus in accordance with FIG. 1;

FIGS. 3A-3E: show a schematic illustration of a second exemplary embodiment of a method according to the disclosure for producing a MEMS mirror array which can be used in the projection exposure apparatus in accordance with FIG. 1;

FIGS. 4A-4E: show a schematic illustration of a third exemplary embodiment of a method according to the disclosure for producing a MEMS mirror array which can be used in the projection exposure apparatus in accordance with FIG. 1; and

FIGS. 5A-5E: show a schematic illustration of a fourth exemplary embodiment of a method according to the disclosure for producing a MEMS mirror array which can be used in the projection exposure apparatus in accordance with FIG. 1.

### DETAILED DESCRIPTION

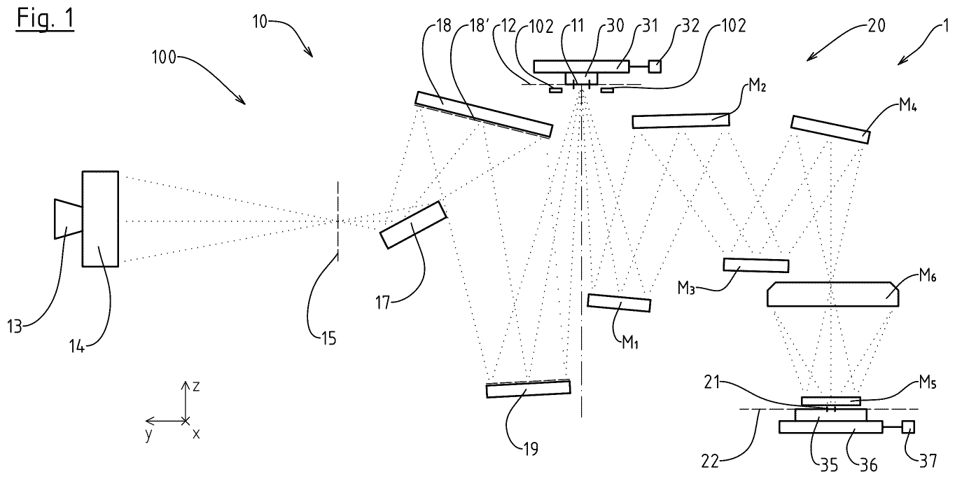

FIG. 1 illustrates a projection exposure apparatus 1 for photolithography in a schematic meridional sectional view. In this case, the projection exposure apparatus 1 comprises an illumination system 10 and a projection system 20, the illumination system 10 being developed with an arrangement 100 according to the disclosure.

An object field 11 in an object plane or reticle plane 12 is illuminated with the aid of the illumination system 10. For this purpose, the illumination system 10 comprises an exposure radiation source 13, which, in the exemplary embodiment illustrated, emits illumination radiation at least comprising used light in the EUV range, i.e. for example having a wavelength of between 5 nm and 30 nm. The exposure radiation source 13 can be a plasma source, for example an LPP (Laser Produced Plasma) source or a DPP (Gas Discharge Produced Plasma) source. A synchrotron-based radiation source can also be involved. The exposure radiation source 13 can also be a free electron laser (FEL).

The illumination radiation emanating from the exposure radiation source 13 is firstly focused in a collector 14. The collector 14 can be a collector having one or more ellipsoidal and/or hyperboloidal reflection surfaces. The at least one reflection surface of the collector 14 can be impinged on by the illumination radiation with grazing incidence (GI), i.e. with angles of incidence of greater than 45°, or with normal incidence (NI), i.e. with angles of incidence of less than 45°. The collector 14 can be structured and/or coated firstly in order to optimize its reflectivity for the used radiation and secondly in order to suppress extraneous light.

Downstream of the collector 14, the illumination radiation propagates through an intermediate focus in an intermediate focal plane 15. If the illumination system 10 is constructed in a modular design, the intermediate focal plane 15 can be used, in general, for the—including structural—separation of the illumination system 10 into a radiation source module, having the exposure radiation source 13 and the collector 14, and the illumination optical unit 16 described below. Given a corresponding separation, radiation source module and illumination optical unit 16 then jointly form a modularly constructed illumination system 10.

The illumination optical unit 16 comprises a deflection mirror 17. The deflection mirror 17 can be a plane deflection mirror or alternatively a mirror having a beam-influencing effect over and above the pure deflection effect. Alternatively or additionally, the deflection mirror 17 can be embodied as a spectral filter that separates a used light wavelength of the illumination radiation from extraneous light of a wavelength deviating therefrom.

The radiation originating from the exposure radiation source 13 is deflected onto a first facet mirror 18 by the deflection mirror 17. If the first facet mirror 18 here—as in the present case—is arranged in a plane of the illumination optical unit 16 which is optically conjugate with respect to the reticle plane 12 as field plane, the facet mirror is also referred to as a field facet mirror.

The first facet mirror 18 comprises a multiplicity of micromirrors 18′ individually pivotable about in each case two axes running perpendicular to one another, for the controllable formation of facets, each of which can be configured with an orientation sensor (not illustrated) for determining the orientation of the micromirror 18′. The first facet mirror 18 is therefore a microelectromechanical system (MEMS system), as is also described in DE 10 2008 009 600 A1, for example.

In the beam path of the illumination optical unit 16, a second facet mirror 19 is disposed downstream of the first facet mirror 18, thus resulting in a doubly faceted system, the basic general of which is also referred to as a fly's eye condenser (fly's eye integrator). If the second facet mirror 19—as in the exemplary embodiment illustrated—is arranged in a pupil plane of the illumination optical unit 16, the facet mirror is also referred to as a pupil facet mirror. However, the second facet mirror 19 can also be arranged at a distance from a pupil plane of the illumination optical unit 16, whereby a specular reflector results from the combination of the first and second facet mirrors 18, 19, as is described in US 2006/0132747 A1, EP 1 614 008 B1 and U.S. Pat. No. 6,573,978, for example.

The second facet mirror 19 need not, in general, be constructed from pivotable micromirrors, but rather can comprise individual facets which are formed from one mirror or a manageable number of mirrors significantly larger than micromirrors and which are either stationary or tiltable only between two defined end positions. It is however—as illustrated—likewise possible, in the case of the second facet mirror 19, to provide a microelectromechanical system having a multiplicity of micromirrors 19′ individually pivotable about in each case two axes running perpendicular to one another, in each case optionally comprising an orientation sensor.

With the aid of the second facet mirror 19, the individual facets of the first facet mirror 18 are imaged into the object field 11, this regularly being only an approximate imaging. The second facet mirror 19 can be the last beam-shaping mirror or else actually the last mirror for the illumination radiation in the beam path upstream of the object field 11.

Each of the facets of the second facet mirror 19 is respectively assigned to exactly one of the facets of the first facet mirror 18 in order to form an illumination channel for illuminating the object field 11. This can result, for example, in illumination according to the Kohler general.

The facets of the first facet mirror 18 are each imaged by an assigned facet of the second facet mirror 19 in a manner being superimposed on one another in order to illuminate the object field 11. In this case, the illumination of the object field 11 is as homogeneous as possible. It can have a uniformity error of less than 2%. The field uniformity can be achieved by way of the superimposition of different illumination channels.

By selecting the illumination channels ultimately used, which is possible without any problems using suitable setting of the micromirrors 18′ of the first facet mirror 18, it is furthermore possible to set the intensity distribution in the entrance pupil of the projection system 20 described below. This intensity distribution is also referred to as an illumination setting. It can moreover be desirable here for the second facet mirror 19 not to be arranged exactly in a plane which is optically conjugate with respect to a pupil plane of the projection system 20. For example, the pupil facet mirror 19 can be arranged tilted relative to a pupil plane of the projection system 20, as is described for example in DE 10 2017 220 586 A1.

In the case of the arrangement of the components of the illumination optical unit 16 as illustrated in FIG. 1, however, the second facet mirror 19 is arranged in an area that is conjugate with respect to the entrance pupil of the projection system 20. The deflection mirror 17 and the two facet mirrors 18, 19 are each arranged tilted both relative to the object plane 12 and with respect to one another.

In an alternative embodiment (not illustrated) of the illumination optical unit 16, a transfer optical unit comprising one or more mirrors can also be provided in the beam path between the second facet mirror 19 and the object field 11. The transfer optical unit can comprise for example one or two normal incidence mirrors (NI mirrors) and/or one or two grazing incidence mirrors (GI mirrors). Using an additional transfer optical unit, it is possible for example to take account of different poses of the entrance pupil for the tangential and for the sagittal beam path of the projection system 20 described below.

It is alternatively possible for the deflection mirror 17 depicted in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

To this end, the projection system 20 comprises a plurality of mirrors Mᵢ, which are consecutively numbered in accordance with their arrangement in the beam path of the projection exposure apparatus 1.

In the example illustrated in FIG. 1, the projection system 20 comprises six mirrors M₁ to M₆. Alternatives with four, eight, ten, twelve or any other number of mirrors M₁ are likewise possible. The penultimate mirror M₅ and the last mirror M₆ each have a passage opening for the illumination radiation, as a result of which the illustrated projection system 20 is a doubly obscured optical unit. The projection system 20 has an image-side numerical aperture that is greater than 0.3 and can also be greater than 0.6, and can be for example 0.7 or 0.75.

The reflection surfaces of the mirrors Mᵢ can be in the form of freeform surfaces without an axis of rotational symmetry. However, the reflection surfaces of the mirrors Mᵢ can alternatively also be designed as aspherical surfaces with exactly one axis of rotational symmetry of the reflection surface shape. Just like the mirrors of the illumination optical unit 16, the mirrors Mᵢ can have highly reflective coatings for the illumination radiation. These reflection coatings can be designed as multilayer coatings, for example with alternating layers of molybdenum and silicon.

The projection system 20 has a large object-image offset in the y-direction between a y-coordinate of a centre of the object field 11 and a y-coordinate of the centre of the image field 21. This object-image offset in the y-direction can be of approximately the same magnitude as a z-distance between the object plane 12 and the image plane 22.

For example, the projection system 20 can be designed to be anamorphic, that is to say it has different imaging scales βₓ, β_{y} in the x- and y-directions for example. The two imaging scales βₓ, β_{y} of the projection system 20 can be (βₓ, β_{y})=(+/−0.25, +/−0.125). An imaging scale β of 0.25 corresponds here to a reduction with a ratio 4:1, while an imaging scale β of 0.125 results in a reduction with a ratio 8:1. A positive sign in the case of the imaging scale β means imaging without image inversion; a negative sign means imaging with image inversion.

Other imaging scales are likewise possible. Imaging scales βₓ, β_{y} with the same sign and the same absolute magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

For example, the projection system 20 can comprise a homocentric entrance pupil. The latter can be accessible. However, it can also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable for example in a scanning direction by way of a reticle displacement drive 32. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable by way of a wafer displacement drive 37 for example longitudinally with respect to the y-direction. The displacement, firstly, of the reticle 30 by way of the reticle displacement drive 32 and, secondly, of the wafer 35 by way of the wafer displacement drive 37 can be implemented so as to be mutually synchronized.

The projection exposure apparatus 1 illustrated in FIG. 1 or its illumination system 10, the above description of which substantially reflects the known prior art, is distinguished by the first and/or second facet mirror 18, 19 comprising one or more MEMS mirror arrays 100 produced according to the disclosure. In this case, each of the MEMS mirror arrays 100 has a multiplicity of individual mirrors 101 which are independently adjustable by in each case two rotational degrees of freedom and which are arranged in a two-dimensional grid. Each of the facet mirrors 18, 19 can be formed by an individual MEMS mirror array or a plurality of MEMS mirror arrays 100 arranged next to one another.

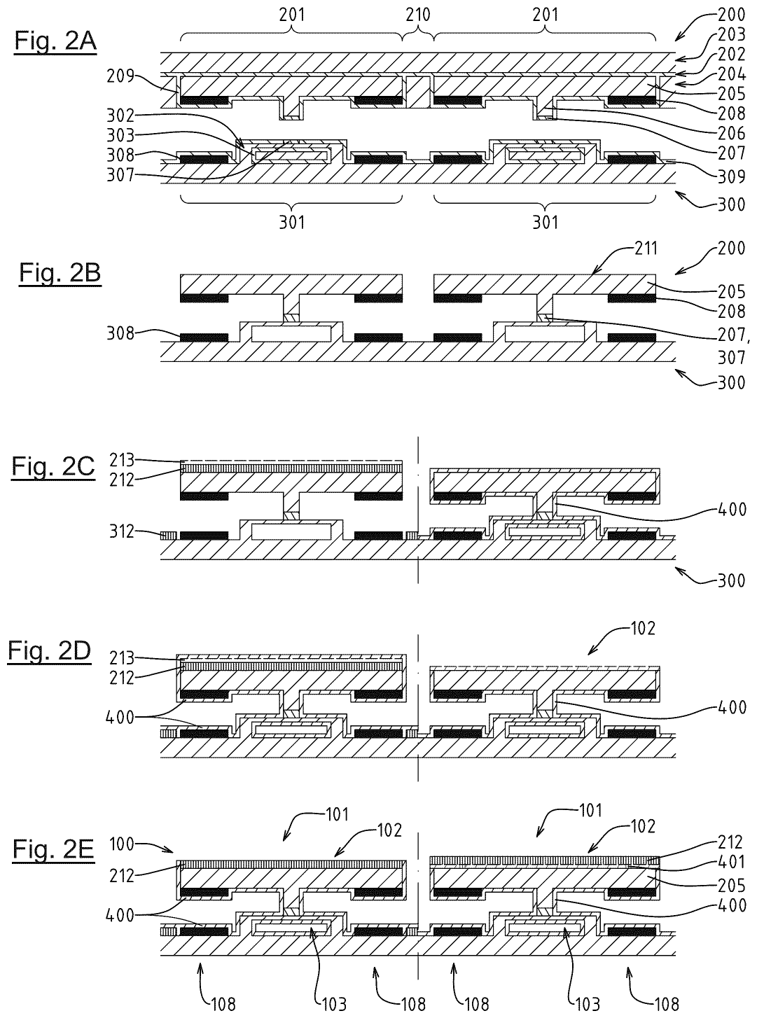

FIGS. 2 to 5 each schematically illustrate different exemplary embodiments of the method according to the disclosure for producing a MEMS mirror array 100 for photolithography, in each case with a plurality of sub-variants. In this case, the figures each show partial sectional views through the MEMS mirror array 100 to be produced, namely through two mirrors 101 or mirror sections 201, in different method stages.

The illustration depicts layers and coatings that are only optionally provided in a specific method step using dashed boundary lines and basically also dashed hatching. That applies to layers and coatings which are optionally applied, and likewise to layers and coatings which are only optionally removed again.

FIGS. 2A-2E show a first exemplary embodiment of a production method according to the disclosure.

At the beginning of the method (FIG. 2A), both a mirror wafer 200 and an actuator wafer 300 are provided.

Proceeding from a planar sandwich wafer as mirror wafer 200 having an inner silicon dioxide layer 202 (also referred to as “silicon-on-insulator wafer” or “SOI wafer”), which has a very smooth surface having a root-mean-square roughness of less than 0.2 nm, such as less than 0.1 nm, and on both sides layers 203, 204, composed of monocrystalline silicon, functional structures are shaped and arranged in one layer 204 in each case in defined mirror sections 201. The respective mirror sections 201 are embodied identically here.

Besides the mirror body 205 forming the later reflection surface 102, the mirror sections 201 comprise as functional structures e.g. in each case a connection column 206 for linking to the actuator wafer 300, a coating 207 suitable for fixed connection to the actuator wafer 300 already being provided on the underside of the column. Furthermore, in each mirror section 201 functional structures 208 are provided which later, together with corresponding structures 308 on the actuator wafer 300, form an actuator 108 for the respective mirror 101. In this case, the schematically depicted actuator 108 represents just one of a number of possible designs for an actuator 108. In the case of other actuator designs, a functional structure 208 is not required in the region of the mirror section 201, and so in this case the mirror wafer 200 can also be embodied completely without functional structures 208.

All the structures 205, 206 and 208 are covered with a layer 209 of silicon dioxide away from the coating 207. This layer 209 may have remained from the production steps for creating the structures 205, 206 and 208 or may have been deliberately applied for protecting the surface of the structures 205, 206 and 208. The layer 209 serves as an etch stop for processes for etching pure silicon.

The structure in the layer 204 is restricted here exclusively to the mirror sections 201. However, when the mirror wafer 200 is provided, the layer 204 is fixedly connected to the silicon dioxide layer 202 and by way of that to the other silicon layer 203, such that the individual mirror sections 201 are a fixed constituent part of the mirror wafer 200. The regions between each two mirror sections 201 are designated as release sections 201 in the present case.

The actuator wafer 300 is based on a planar silicon layer composed of monocrystalline and/or polycrystalline silicon, on which various functional structures are shaped in actuator sections 301 constructed identically in each case. Functional structures 308 are provided, inter alia, which later, together with the corresponding structures 208 on the mirror wafer 200, form an actuator 108 that enables the mirror 101 to be adjusted, namely pivoted, by a predefined degree of freedom.

Furthermore, a joint structure 302 is provided, too, which is pervaded by silicon dioxide layers 303 serving as an etch stop for subsequent method steps used to create a flexure 103 from the joint structure 302, the flexure enabling an adjustment in two independent degrees of freedom for the mirror 101. A coating 307 suitable for fixed connection is provided in that region of the joint structure 302 which is provided for connection to the connection column 206 of the mirror wafer 200. Apart from the region of precisely this coating 307, the actuator wafer 300 is covered with a silicon dioxide layer 309 on the side provided for connection to the mirror wafer 200.

The mirror wafer 200 and actuator wafer 300 thus provided are placed one on top of the other with an accuracy of 2 μm, such as less than 1 μm, in such a way that the coatings 207, 307 come into contact with one another. Depending on the configuration of the coatings 207, 307, these can already be activated just by the contact and establish a permanent and fixed connection between the mirror wafer 200 and actuator wafer 300. Alternatively, the coatings 207, 307 can also be activated separately, e.g. thermally or by plasma.

Afterwards, the silicon layer 203 of the mirror wafer 200 is firstly removed, e.g. by etching using a plasma (e.g. SF6) or using a chemical (e.g. XeFE₂). In the course of this or in separate steps, the portions of the joint structure 302 on the actuator wafer 300 which are delimited by the silicon dioxide layers 303 are removed as well. In this case, as known from the prior art, it is also possible to create openings on the rear side of the actuator wafer 300, for example in the region of the joint structure 302.

At least one portion of the silicon layer 203 can also be removed by grinding and polishing, optionally using chemical mechanical polishing, with an etching step optionally following, also in order to uncover the joint structure 302 on the actuator wafer 300.

Afterwards, all uncovered silicon dioxide layers 202, 209, 303, 309 are also removed without residues (e.g. using hydrogen fluoride vapours).

The result of the steps described above is illustrated in FIG. 2B.

Up until this stage, the method shown in FIGS. 2A-2E correspond to known prior art and can be implemented directly by a person skilled in the art. The described method steps are e.g. also described in DE 10 2015 220 018 A1, which furthermore also shows in detail a possible configuration of the individual structures, only illustrated schematically in the present case.

In the production state illustrated in FIG. 2B, in general the mirror body 205 can already be can be adjusted with the actuators 108 formed by the functional structures 208, 308 on mirror wafer 200 and actuator wafer 300 in one of the degrees of freedom created by the joint structure 302. What are missing, however, are not only the reflection coating 212—desired for the reflection of EUV radiation—in the region of the provided reflection surfaces 211 but also the protective layer 400 against environmental influences, this protective layer being provided according to the disclosure.

In a first variant, which is elucidated in FIGS. 2C, 2D and 2E in each case with reference to the left-hand mirror 101 or mirror/actuator sections 201, 301 illustrated, firstly the reflection coating 212 is applied (FIG. 2C, on the left). In the present exemplary embodiment here the reflection coating 212 is constructed from a plurality of alternating layers of silicon and molybdenum that are applied successively by methods known for this purpose with suitable layer thicknesses in order to make the reflection surfaces 211 reflective to EUV radiation having a wavelength of 13.5 nm. For other wavelengths, the reflection surfaces 211 should, if appropriate, be formed from other suitable material and/or layer construction.

In this case, the surface in the region of the reflection surfaces 211 generally has a sufficiently high surface quality to apply the reflection coating 212 directly thereon, since the silicon dioxide layer 202 with very low surface roughness was only recently removed. Alternatively, suitable surface processing steps should be provided for the reflection surfaces 211, such as e.g. chemical mechanical polishing, although desirable to carry out before the removal of the release sections 210, for which reason the surface to be polished should in this case likewise be uncovered before the removal of the release sections 210.

During the application of the coating 212, regions 312 having reflective properties can also form in the region of the actuator wafer 300. However, these regions 312 are non-critical for the later use of the MEMS mirror array 100 and can remain. If they were nevertheless critical, they can be removed or covered with non-reflective material in a later processing step.

Optionally—and therefore only illustrated by dashed lines—a reflection coating protective layer 213 can be provided on the reflection coating 212, and protects the reflection coating 212 against damage during the subsequent processing steps. For example, the reflection coating protective layer 213 can also assist in removing again layers subsequently applied over the reflection coating 212. The reflection coating protective layer 213 can be applied e.g. by sputtering, atomic layer deposition or chemical or physical vapour deposition.

After the application of the reflection coating 212 and—optionally—the reflection coating protective layer 213, at least that surface of the MEMS mirror array 100 which comes into contact with the atmosphere or the vacuum in the interior of the projection exposure apparatus 1 during the later use is covered with a protective layer 400 against environmental influences. In this case, the protective layer 400 has a high uniformity and form an impervious, continuous layer even on surfaces that are difficult to access. In order to achieve this, the protective layer 400 can be applied e.g. by atomic layer deposition or chemical vapour deposition.

If the protective layer 400 against environmental influences is intended to prevent hydrogen-induced outgassing, for example, electrically insulating substances, such as aluminium oxide (AlₓO_{y}) or titanium oxide (TiₓO_{y}), are suitable for this purpose. However, electrically conductive substances or a multilayer construction are/is also possible for the protective layer 400 against environmental influences.

As is directly evident from FIG. 2D, on the left, the protective layer 400 against environmental influences also extends over the reflection coating 212. If the protective layer 400 here is completely transmissive to light which in general is reflectable by the reflection coating 212, i.e. EUV light having a wavelength of 13.5 nm in the present case, the protective layer 400 against environmental influences can remain on the reflection coating 212. The reflection coating protective layer 213 is very generally dispensed with in this case. The production method is ended with FIG. 2D in this case.

It is alternatively possible to remove the protective layer 400 against environmental influences from the reflection coating 212, for which purpose a reflection coating protective layer 213 may regularly prove to be helpful in protecting the reflection coating 212 against damage during the removal of the protective layer 400 against environmental influences. The reflection coating protective layer 213 should finally likewise be removed, thus resulting in the end state shown in FIG. 2E, on the left.

Instead of the procedure of applying firstly the reflection coating 212 and only afterwards the protective layer 400 against environmental influences, which procedure is elucidated with reference to FIGS. 2C, 2D and 2E on the left in each case with reference to the left-hand mirror 101 or mirror/actuator sections 201, 301 illustrated, an opposite order is also possible, which is elucidated below with reference to the mirror 101 or mirror/actuator sections 201, 301 illustrated in each case on the right in FIGS. 2C, 2D and 2E.

Proceeding from the state shown in FIG. 2B, at least that surface of the MEMS mirror array 100 which comes into contact with the atmosphere or the vacuum in the interior of the projection exposure apparatus 1 during the later use is covered directly with a protective layer 400 against environmental influences (cf. FIG. 2C, on the right). For the desired properties of the protective layer 400 and the possible application methods, reference is made to the explanations above.

The protective layer 400 against environmental influences can be suitable, in general, for allowing the reflection coating 212 to be applied directly thereon. For this purpose, the protective layer 400 has a sufficient surface quality and strength, which is either afforded directly or can be ensured by suitable subsequent processing of the protective layer 400 in the region of the later reflection surface 102.

If the protective layer 400 against environmental influences is not suitable for allowing the reflection coating 212 to be applied thereon or the possibly desired electrical connection between reflection coating and mirror body 205 cannot be ensured, the protective layer 400 should be removed in the region of the reflection surface 102, which is indicated in FIG. 2D, on the right, by the dashed illustration of the protective layer 400 in precisely this reason 102. In order to facilitate the removal of the protective layer 400 in the region of the reflection surface 102, a temporary layer (not illustrated) can also be provided below the protective layer 400 against environmental influences, which temporary layer protects the mirror body 205 against damage during the regional detachment of the protective layer 400 and for example can assist in attaining or maintaining a high surface quality. In this case, the temporary layer may have been applied before or after the removal of the release sections 210.

Finally, the reflection coating 212 is applied in the region of the reflection surface 102—either directly onto the previously uncovered mirror body 205 or onto the protective layer 400 against environmental influences that has remained there.

Depending on the reflection coating 212, it is desirable for this reflection coating to be electrically connected to the mirror body 205. If the protective layer 400 against environmental influences has remained between the reflection coating 212 and the mirror body 205, and if this protective layer is not electrically conductive, it is possible, for example, as indicated in FIG. 2E, on the right, to provide suitable vias 401 through the protective layer 400, which vias can be created at a suitable time in the production method e.g. using plasma etching, ion milling, ion or electron polishing, laser ablation or selective atomic layer deposition etching. Alternatively, it is conceivable for the protective layer 400 that is insulating, in general, to be made sufficiently conductive by suitable subsequent processing, such as e.g. the introduction of ions by irradiation, directional deposition or incandescence, e.g. by the resistivity being reduced to 1 to 1000 MΩ×m²/m.

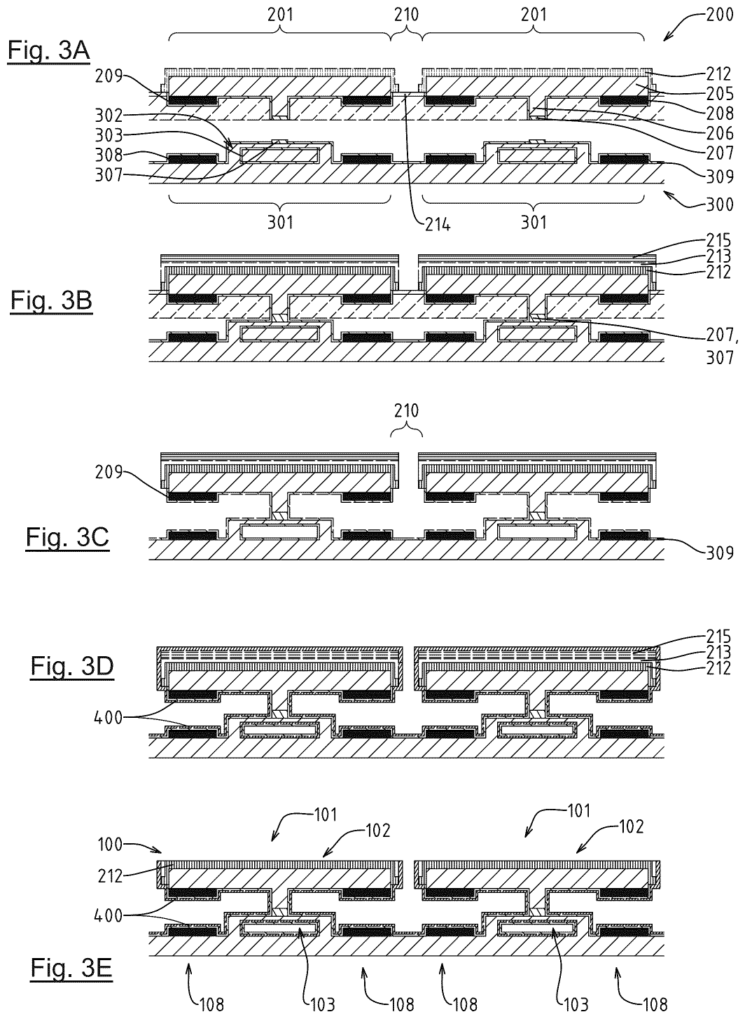

FIGS. 3A-3E show a second exemplary embodiment of a production method according to the disclosure. In this case, various structural features of the MEMS mirror array 100 produced and also individual method steps here are similar to those from FIGS. 2A-2E. The focus below is therefore on the special characteristics of the production method in accordance with FIGS. 3A-3E, reference additionally being made to the above explanations concerning FIGS. 2A-2E for example for more specific details concerning the materials and processes used.

At the beginning of the method (FIG. 3A), both a mirror wafer 200 and an actuator wafer 300 are provided. The actuator wafer 300 here is configured identically to FIG. 2A, for which reason reference is made to the explanations in respect thereof. Much of the mirror wafer 200, too, is constructed in a manner comparable with that from FIGS. 2A-2E, for example with regard to the mirror body 205 and the functional structures 206 and 208 linked thereto.

However, the rear side of the mirror bodies 205 is uncovered and optionally—and therefore only illustrated by dashed lines—already provided with a reflection coating 212 in this stage.

Since the mirror wafer 200 lacks the structurally supporting layer 203 composed of silicon (cf. FIGS. 2A-2E) or this layer has already been removed, possibly only a comparatively thin material bridge 214 is provided in the release sections 210. If the material bridge 214 cannot ensure enough structural integrity of the mirror body 205, optionally the region adjacent thereto, illustrated by dashed lines, can however also be composed of silicon, for example monocrystalline and/or polycrystalline silicon, whereby significantly more stability can be imparted to the mirror wafer 200.

As explained in association with FIGS. 2A-2E, mirror wafer 200 and actuator wafer 300 are joined together with high precision, such that the two wafers 200, 300 are fixedly connected to one another with the aid of the coatings 207, 307 provided therefor.

The reflection coating 212, if not already present, should be provided at the latest after the joining together. A photoresist layer 215 should be provided thereon, and protects the reflection coating 212 in the subsequent processing steps, for example possible etching processes. Optionally, a reflection coating protective layer 213 can be provided between reflection coating 212 and photoresist layer 215, and can protect the reflection coating 212 during later processing steps, for example the removal of other layers arranged on the reflection coating protective layer 213, and—given suitable configuration—can also serve as an etch stop for the later processing steps.

Afterwards, at least the material in the release section 210 is removed, e.g. using a vertical etching process, as well as other, without disturbing silicon (cf. FIG. 3C). The silicon dioxide layers 209, 309 serve as an etch stop for this. These silicon dioxide layers 209, 309 can also be removed afterwards. This is not necessary, however, for which reason the layers in question are illustrated by dashed lines in FIG. 3C.

Depending on the method variant, the photoresist layer 215 and/or the reflection coating protective layer 213 can subsequently be removed as desired. This is not absolutely necessary, however, in all method variants, and so the layers 213, 215 in question are consequently illustrated by dashed lines in FIG. 3D.

The protective layer 400 against environmental influences is then applied to all surface area of the MEMS mirror array 100 which comes into contact with the atmosphere or the vacuum in the interior of the projection exposure apparatus 1 during the later use (cf. FIG. 3D). The protective layer 400 here can be applied on the silicon dioxide layers 209, 309 or—in the case of the latter having been previously removed—directly on the underlying structure, and also—depending on the preceding processing steps—on the reflection coating 212, the photoresist layer 215 and/or the reflection coating protective layer 213.

If the protective layer 400 against environmental influences is transmissive to the light to be reflected by the reflection coating 212 and is intended to remain permanently on the latter, the method is ended in the state shown in FIG. 3D—where in this case the photoresist layer 215 and/or the reflection coating protective layer 213 should very generally be removed before the application of the protective layer 400 against environmental influences.

If the protective layer 400 against environmental influences is intended to be removed in the region of the reflection coating 212, e.g. because it is not sufficiently light-transmissive, this should be done using suitable processing processes. In the course of this, layers that may have remained, such as the photoresist layer 215 and/or the reflection coating protective layer 213, can then also be removed, such that—as shown in FIG. 3E—the reflection surface 102 is formed directly by the reflection coating 212.

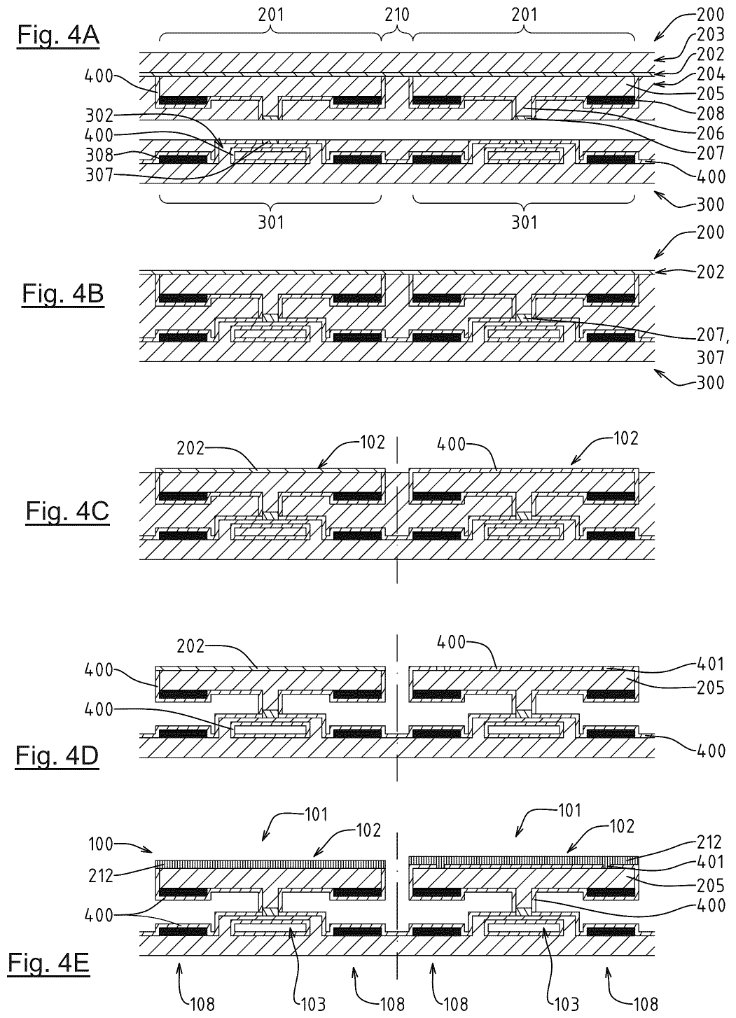

FIGS. 4A-4E show a third exemplary embodiment of a production method according to the disclosure for MEMS mirror arrays 100. In this case, the steps of the method and the materials and structures used therein are similar to those from FIGS. 2A-2E and 3A-3E, for which reason reference is made in general to the explanations above, and exclusively the special characteristics of the method in accordance with FIGS. 4A-4E are explained below.

As evident in FIG. 4A, mirror wafer 200 and actuator wafer 300 are in general constructed in a manner comparable with those in FIGS. 2A-2E, for example FIG. 2A, even though additional silicon material is provided on the mirror wafer 200, whereby the latter acquires a plane surface on both sides.

A special characteristic by comparison with the embodiment in accordance with FIGS. 2A-2E, however, is that the silicon dioxide layers 209, 303, 309 provided there are already embodied in the present case as a protective layer 400 against environmental influences, i.e. for example are composed of material suitable therefor. At the same time, this protective layer 400 against environmental influences also serve as an etch stop for subsequent method steps, such that the protective layer 400 and the relevant etching processes are coordinated with one another. Alternatively, it is also possible to provide a combination of protective layer 400 and an etch stop layer, e.g. composed of silicon dioxide, as a multilayer.

After mirror wafer 200 and actuator wafer 300 have been joined together, the coatings 207, 307 fixedly bonding with one another, the one layer 203 of monocrystalline silicon is removed by etching, the silicon dioxide layer 202 forming an etch stop (cf. FIG. 4B).

The silicon dioxide layer 202 is subsequently removed at least in the regions away from the mirror sections 201, i.e. for example in the release sections 210 (FIG. 4C, on the left). Alternatively, the silicon dioxide layer 202 can also be completely removed and a protective layer 400 against environmental influences can be applied in the mirror sections 201 (FIG. 4C, on the right). The protective layer 400 against environmental influences that is applied in this step can in this case be of a type identical to the inner protective layers 400 within the mirror wafer 200 and actuator wafer 300. However, it is also possible to apply a protective layer 400 against environmental influences which has different material properties compared with the inner protective layers 400 mentioned. In this regard, the protective layer 400 against environmental influences which is to be applied can be electrically conductive, for example.

Afterwards, unwanted silicon is removed from the various interspaces using an etching process. In this case—as already mentioned—the protective layer 400 against environmental influences serves as an etch stop (FIG. 4D).

If the silicon dioxide layer 202 had still been partly retained (FIG. 4D, on the left), it should now be removed in order subsequently to apply the reflection layer 212 to the reflection surface 102 of the mirror 101.

If the mirror body 105 is completely surrounded by the protective layer 400 against environmental influences (FIG. 4D, on the right), the protective layer 400 in the region of the reflection surface 102—particularly if it is composed of an electrically insulating material—can be provided with vias 401 as desired or its conductivity can be increased by way of suitable treatment.

Finally, the reflection layer 212 can then be applied to the protective layer 400 against environmental influences (FIG. 4E, on the right). If the protective layer 400 previously applied in the region of the reflection surface 102 were removed before the application of the reflection layer 212, this results in the construction in accordance with FIG. 4E, on the left.

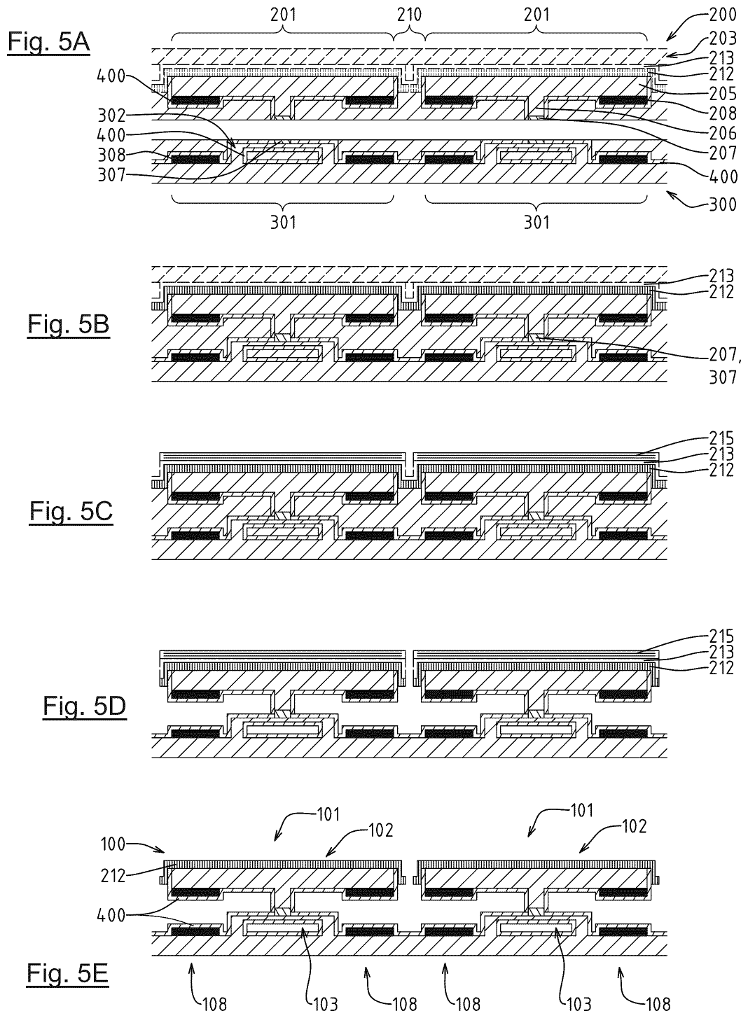

FIGS. 5A-5E show a fourth exemplary embodiment of a production method according to the disclosure. Here, too, initially reference is made to the above explanations concerning FIGS. 2 to 4, and so the elucidations below can concentrate on the special characteristics of this fourth exemplary embodiment.

Much of the mirror wafer 200 and the actuator wafer 300 is identical, in terms of their provision, to that from FIGS. 4A-4E. For example, the various inner layers provided as an etch stop are embodied directly as protective layers 400 against environmental influences. In this case, the protective layers 400 against environmental influences can serve directly as an etch stop. Alternatively, it is also possible to provide a combination of protective layer 400 and an etch stop layer, e.g. composed of silicon dioxide, as a multilayer.

Those regions of the mirror bodies 205 which later serve as the reflection surface 102 are either uncovered or else already provided with a reflection coating 212 (therefore only illustrated by dashed lines in FIG. 5A). Particularly if a reflection coating 212 is provided, a reflection coating protective layer 213 can also be arranged thereon (likewise illustrated by dashed lines).

In order to further increase the structural integrity of the mirror wafer 200 or in order to be able to better process and grip this wafer mechanically, a further layer 203 of silicon can be provided on the side facing away from the connection columns 206.

After the joining together of mirror wafer 200 and actuator wafer 300 (FIG. 5B), a reflection coating 212 should be provided in any case. Depending on the configuration of the mirror wafer 200 during the provision thereof, the reflection coating 212 is to be applied as well or else the silicon layer 203 is to be removed from a reflection coating 212 already present. Whether a reflection coating protective layer 213 is provided or possibly remains after the removal of the silicon layer 203 is optional, in general, but generally desirable.

Exclusively in the mirror sections 201, a photoresist layer 215 is applied (FIG. 5C) to the reflection coating 212 or a reflection coating protective layer 213 possibly arranged thereon, and protects the reflection coating 212 within the mirror sections 201 during the subsequent etching process in which undesired silicon is removed (FIG. 5D).

Finally, the photoresist layer 215 and residues of the reflection coating protective layer 213 possibly present are also removed, thus resulting in the state illustrated in FIG. 5E and a MEMS mirror array 100 produced according to the disclosure.

The above-described exemplary embodiments of methods according to the disclosure for producing a MEMS mirror array 100 are not exhaustive. For example, in the course of production, various additional steps, e.g. for surface processing, can also be provided in order that the reliability, accuracy and reflection properties of the resulting MEMS mirror array 100 can be improved even further. However, the steps which the individual exemplary embodiments have in common, in general, form the basic framework of the production method according to the disclosure.

What is claimed is:

1. A method of making a MEMS mirror array comprising a number of individual mirrors adjustable by at least one degree of freedom, the method comprising:
a) providing a mirror wafer comprising a number of mirror sections separated from one another by release sections, the number of mirror sections corresponding to the number of adjustable mirrors;
b) providing an actuator wafer comprising a number of actuator sections corresponding to the number of adjustable mirrors, the actuator sections being spaced apart from one another according to the mirror sections, the actuator sections being provided with at least one functional structure;
C) joining together the mirror wafer and the actuator wafer so that, in each case, a mirror section is fixedly connected to a respective actuator section in defined regions; and
d) removing the release sections so that each individual mirror section is adjustable relative to its respective actuator section by at least one degree of freedom using at least one portion of the functional structures,
wherein before or after at least one of a)-d), at least regions of the mirror wafer and/or of the actuator wafer are provided with a protective layer against environmental influences to protect the underlying material against hydrogen-induced outgassing.

2. The method of claim 1, wherein the protective layer is provided on all surfaces of the MEMS mirror array which are susceptible to hydrogen-induced outgassing.

3. The method of claim 1, comprising providing at least one portion of the protective layer after d).

4. The method of claim 3, wherein the protective layer is provided on all surfaces of the MEMS mirror array which are susceptible to hydrogen-induced outgassing.

5. The method of claim 1, comprising, before a), providing at least one portion of the protective layer on the mirror wafer and/or the actuator wafer.

6. The method of claim 5, wherein the protective layer is provided on all surfaces of the MEMS mirror array which are susceptible to hydrogen-induced outgassing.

7. The method of claim 1, comprising, before a), integrating at least one portion of the protective layer into the mirror wafer and/or actuator wafer.

8. The method of claim 1, wherein the protective layer comprises an etch stop.

9. The method of claim 1, when the protective layer serves as an etch stop during d).

10. The method of claim 1, wherein an outer surface of the mirror sections define reflection surfaces of the MEMS mirror array, and the mirror sections are protected against damage by a layer.

11. The method of claim 1, further comprising, before or after at least one a)-d) and before or after applying the protective layer, applying a reflection coating to regions provided as reflection surfaces.

12. The method of claim 11, further comprising, before or after applying the reflection coating, removing the protective layer.

13. The method of claim 11, further comprising increasing an electrical conductivity of the protective layer within the regions.

14. The method of claim 11, wherein increasing the electrical conductivity comprises introducing vias or reducing the electrical resistivity.

15. The method of claim 1, wherein the protective layer is transmissive to light in the EUV range.

16. The method of claim 1, wherein the mirrors are adjustable by two degrees of freedom.

17. The method of claim 1, wherein the mirrors are adjustable by two rotational degrees of freedom running perpendicular to one another.

18. A method, comprising:
providing a mirror wafer comprising a number of mirror sections separated from one another by release sections;
providing an actuator wafer comprising a number of actuator sections corresponding to the number of mirror sections, the actuator sections being spaced apart from one another according to the mirror sections, the actuator sections being provided with at least one functional structure;
joining together the mirror wafer and the actuator wafer so that, in each case, a mirror section is fixedly connected to a respective actuator section in defined regions;
removing the release sections so that each individual mirror section is adjustable relative to its respective actuator section by at least one degree of freedom using at least one portion of the functional structures; and
before or after at least one of the preceding steps, providing at least regions of the mirror wafer and/or of the actuator wafer with a protective layer against environmental influences to protect the underlying material against hydrogen-induced outgassing,
wherein the method makes a MEMS mirror array comprising a number of individual mirrors adjustable by at least one degree of freedom, the number of individual mirrors corresponding to the number of mirror sections.

19. The method of claim 18, further comprising disposing the MEMS mirror array in a photolithography projection exposure apparatus.

20. The method of claim 18, further comprising disposing the MEMS mirror array in a photolithography illumination system.
